(19) United States
(12) Patent Application Publication
(10) Pub. No.: US 2022/0123179 A1
(43) Pub. Date: Apr. 21, 2022

(54) SEMICONDUCTOR MODULE

(71) Applicant: Sharp Fukuyama Semiconductor Co., Ltd., Fukuyama City (JP)

(72) Inventors: HIROAKI ONUMA, Fukuyama City (JP); MASUMI MAEGAWA, Fukuyama City (JP); Kei URAKAWA, Fukuyama City (JP); Kentaro KUBOTA, Fukuyama City (JP); Shotaro OIE, Fukuyama City (JP)

(21) Appl. No.: 17/503,586

(22) Filed: Oct. 18, 2021

(30) Foreign Application Priority Data
Oct. 21, 2020 (JP) 2020-176743

(51) Int. Cl. H01L 33/50; H01L 33/54; H01L 25/16

(52) U.S. Cl. CPC H01L 33/502; H01L 25/167; H01L 33/54

(57) ABSTRACT

A semiconductor module comprises an underlayer substrate on which a drive circuit is formed; a light-emitting element electrically coupled to the drive circuit; and a color conversion layer formed on the light-emitting element and containing a color conversion material that absorbs light emitted from the light-emitting element and converts a luminescent color of the light-emitting element to another luminescent color, wherein the color conversion material contained in the color conversion layer is present more on a light-emitting element side of the color conversion layer than on a side opposite to the light-emitting element side of the color conversion layer.

### CROSS-REFERENCE TO RELATED APPLICATION

The present application claims priority from Japanese Application JP2020-176743, the content of which is hereby incorporated by reference into this application.

### BACKGROUND

### 1. Field

One aspect of the present disclosure relates to a semiconductor module.

JP 2015-126209 A discloses a light-emitting apparatus including a substrate, a first light-emitting element, a second light-emitting element, a first light-transmitting member, a second light-transmitting member, and a light blocking member. The first light-emitting element and the second light-emitting element are arranged on the substrate, and the first light-transmitting member and the second light-transmitting member are arranged on upper faces of the first light-emitting element and the second light-emitting element, respectively. The light blocking member covers side surfaces of the first light-emitting element and the second light-emitting element and side surfaces of the first light-transmitting member and the second light-transmitting member.

### SUMMARY

The technique disclosed in JP 2015-126209 A aims to stabilize the characteristics of the light-emitting apparatus, and is not intended to flatten the upper faces of the first light-transmitting member and the second light-transmitting member. One aspect of the present disclosure is to improve the flatness of a surface of a color conversion layer on a side opposite to a light-emitting element side.

By improving the flatness of the color conversion layer, layers having functions of improving optical characteristics and reliability, respectively, can be formed on the entire upper surface of the color conversion layer with uniform thicknesses and uniform shapes, and thus it is easy to make the light emission characteristics on the respective light-emitting elements uniform.

In order to solve the above problems, a semiconductor module according to one aspect of the present disclosure includes an underlayer substrate on which a drive circuit is formed, a light-emitting element electrically coupled to the drive circuit, and a color conversion layer formed on the light-emitting element and containing a color conversion material that absorbs light emitted from the light-emitting element and converts a luminescent color of the light-emitting element to another luminescent color, and the color conversion material contained in the color conversion layer is present more on a light-emitting element side of the color conversion layer than on a side opposite to the light-emitting element side of the color conversion layer.

Further, a semiconductor module according to one aspect of the present disclosure includes an underlayer substrate on which a drive circuit is formed, a light-emitting element electrically coupled to the drive circuit, a color conversion layer formed on the light-emitting element and configured to absorb light emitted from the light-emitting element and convert a luminescent color of the light-emitting element to another luminescent color, and a protection layer formed on the color conversion layer and configured to protect an upper portion of the color conversion layer.

According to one aspect of the present disclosure, the flatness of the surface of the color conversion layer on the side opposite to the light-emitting element side can be improved.

### BRIEF DESCRIPTION OF THE DRAWINGS

FIG. 1 is cross-sectional views illustrating configuration of semiconductor modules according to a first embodiment of the present disclosure.

FIG. 2 is a diagram for describing a manufacturing method of the semiconductor modules illustrated in FIG. 1.

FIG. 3 is cross-sectional views illustrating configurations of semiconductor modules according to a second embodiment of the present disclosure.

FIG. 4 is cross-sectional views illustrating configurations of semiconductor modules according to a third embodiment of the present disclosure.

FIG. 5 is a diagram for describing a manufacturing method of the semiconductor modules illustrated in FIG. 4.

FIG. 6 is a diagram for describing a first modified example of the manufacturing method of the semiconductor modules illustrated in FIG. 4.

FIG. 7 is a diagram for describing a second modified example of the manufacturing method of the semiconductor modules illustrated in FIG. 4.

FIG. 8 is cross-sectional views illustrating configurations of semiconductor modules according to a fourth embodiment of the present disclosure.

FIG. 9 is a diagram for describing a manufacturing method of the semiconductor modules illustrated in FIG. 8.

FIG. 10 is cross-sectional views illustrating configurations of semiconductor modules according to a fifth embodiment of the present disclosure.

FIG. 11 is a diagram showing the intensity of light emitted from a semiconductor module according to one example of the present disclosure.

FIG. 12 is a diagram illustrating a cross sectional view of a color conversion layer and a function layer of a semiconductor module according to one example of the present disclosure.

### DESCRIPTION OF EMBODIMENTS

### First Embodiment

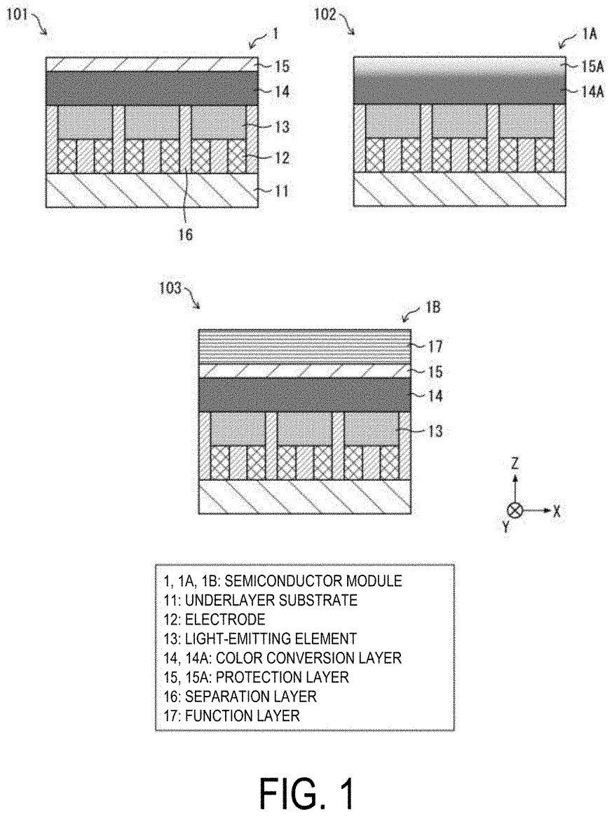

FIG. 1 is cross-sectional views illustrating configurations of semiconductor modules 1, 1A, and 1B according to a first embodiment of the present disclosure. The semiconductor modules 1A and 1B are modified examples of the semiconductor module 1. Reference numerals 101, 102, and 103 in FIG. 1 indicate the configurations of the semiconductor modules 1, 1A, and 1B, respectively. In FIG. 1, a direction in which a plurality of light-emitting elements 13 are aligned is taken as an X direction, a direction from an underlayer substrate 11 toward the light-emitting element 13 is a positive direction of Z, and a direction orthogonal to both the X direction and the Z direction is taken as a Y direction. In addition, the positive direction of Z may be an upward direction.

### Configuration of Semiconductor Module 1

As illustrated by reference numeral 101 in FIG. 1, the semiconductor module 1 includes the underlayer substrate 11, electrodes 12, the plurality of light-emitting elements 13, a color conversion layer 14, a protection layer 15, and a separation layer 16. The underlayer substrate 11 is formed with a wiring line so that a surface of the underlayer substrate 11 can be coupled to at least the light-emitting element 13. A drive circuit that drives the light-emitting element 13 is formed on the underlayer substrate 11. A material of the underlayer substrate 11 is, for example, silicon (Si).

The plurality of light-emitting elements 13 are electrically coupled to the drive circuit formed on the underlayer substrate 11 via the electrodes 12 constituted of gold (Au). As the light-emitting element 13, a known light-emitting element, specifically, a semiconductor light-emitting element can be used, and for example, a GaAs-based, a ZnO-based, or a GaN-based light-emitting element can be used. The plurality of light-emitting elements 13 are arranged side by side in the X direction, but a plurality of light-emitting elements 13 may be arranged side by side in the Y direction as well.

As the light-emitting element 13, a light emitting diode (LED) that emits visible light of red, orange, yellow, yellow-green, green, blue-green, blue, blue-violet, or violet may be used, or an LED that emits near-ultraviolet light may be used. Among them, the GaN-based semiconductor capable of emitting blue to ultraviolet light is preferably used as the light-emitting element 13. Here, the light-emitting element 13 which is an InGaN semiconductor that emits blue light will be described. The light emitted by the light-emitting element 13 is emitted from an upper face (on the side opposite to the underlayer substrate 11 side), so that the semiconductor module 1 functions as a display element.

The separation layer 16 is arranged between the light-emitting elements 13 adjacent each other, and separates the plurality of light-emitting elements 13. The separation layer 16 covers the upper face of the underlayer substrate 11, and side surfaces of the electrodes 12 and the light-emitting elements 13. The separation layer 16 is a light shielding layer that suppresses optical crosstalk due to light emitted from the side surface of the light-emitting element 13 perpendicular to an XY plane. In addition, the separation layer 16 may have a function of fixing the electrode 12 and the light-emitting element 13 to the underlayer substrate 11.

The separation layer 16 is also called an underfill, and is formed by curing a liquid resin as an example. Further, as another example, the separation layer 16 is formed of a metal material such as Al or Cu, and is formed by using a damascene process or the like. Note that the separation layer 16 may be constituted of only a single-material such as an epoxy resin or a metal, or may be constituted of a combination of a plurality of materials such as a combination of a metal and a resin, a combination of a resin and a dye, or a combination of a resin and oxide particles.

Note that the light-emitting elements 13 are not completely separated from each other by the separation layer 16, and may be partially separated from each other. That is, the light-emitting elements 13 may be partially separated from each other on the underlayer substrate 11 side and filled with the separation layer 16, and the light-emitting elements 13 may not be separated from each other on the opposite side.

The color conversion layer 14 is formed on the plurality of light-emitting elements 13 and the separation layer 16, and contains a color conversion material that absorbs the light emitted from the light-emitting element 13 and converts a luminescent color of the light-emitting element 13 into another luminescent color. The color conversion material is uniformly present inside the color conversion layer 14. The color conversion material converts the wavelength of the light emitted by the light-emitting element 13. By forming the color conversion layer 14 on the light-emitting element 13, various luminescent colors in the visible light region can be exhibited.

The color conversion layer 14 is made of a color conversion material such as a quantum dot (QD), a phosphor material containing a nanophosphor, or a light-absorbing material. Further, the color conversion layer 14 may be constituted of the color conversion material and a resin that is a base material. Furthermore, the color conversion layer 14 may contain a light scattering material such as titania, silica, or alumina. The color conversion layer 14 is, for example, a green conversion layer or a red conversion layer. When the color conversion layer 14 is the green conversion layer, the color conversion layer 14 converts the light emitted by the light-emitting element 13 into green light. When the color conversion layer 14 is the red conversion layer, the color conversion layer 14 converts the light emitted by the light-emitting element 13 into red light.

The protection layer 15 is formed on the color conversion layer 14 and protects an upper portion of the color conversion layer 14. The protection layer 15 having a substantially uniform thickness is formed on the color conversion layer 14 such that an upper face of the protection layer 15 is flat. As a result, even when an upper face of the color conversion layer 14 is uneven due to the particles of the color conversion material, the protection layer 15 is formed on the upper face of the color conversion layer 14 where unevenness is generated. Thus, compared with a case in which the protection layer 15 is not formed on the color conversion layer 14, the flatness of the surface of the color conversion layer 14 on the side opposite to the light-emitting element 13 side can be improved.

In addition, since the protection layer 15 is formed on the color conversion layer 14, the flatness of the upper face of the protection layer 15 is higher than the flatness of the upper face of the color conversion layer 14. In other words, the flatness of the surface of the protection layer 15 on the side opposite to the color conversion layer 14 side is higher than the flatness of the surface of the protection layer 15 on the color conversion layer 14 side. As a result, the protection layer 15 can improve the flatness of the upper face of the color conversion layer 14.

Examples of the protection layer 15 include a transparent resin, an oxide film, a nitride film, and diamond-like carbon (DLC). When the protection layer 15 is the transparent resin, the protection layer 15 can be formed on the color conversion layer 14 by coating, and the unevenness generated on the upper face of the color conversion layer 14 can be easily reduced by the protection layer 15.

As the protection layer 15, it is preferable to use a material having high gas barrier properties. In this case, since the color conversion layer 14 is shielded from the atmosphere by the protection layer 15, deterioration over time of the color conversion layer 14 can be suppressed. As a result, the light extraction efficiency from the color conversion layer 14 can be improved.

### Manufacturing Method of Semiconductor Module 1

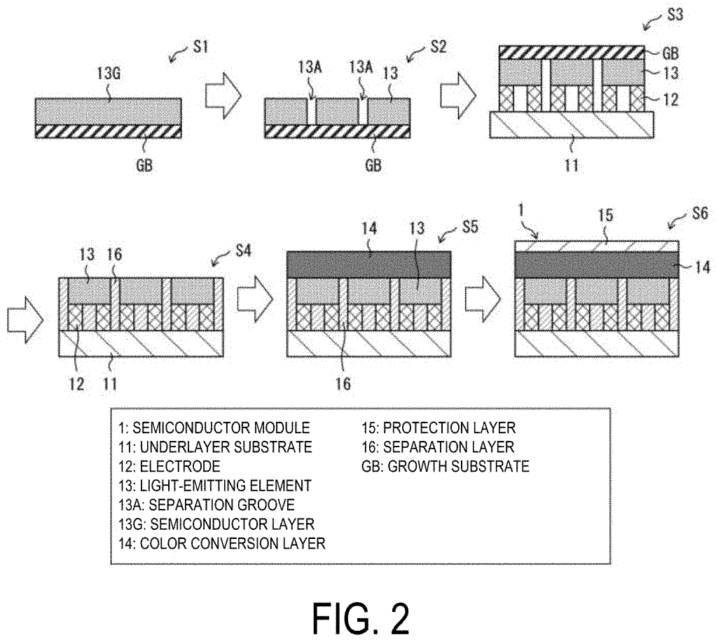

FIG. 2 is a diagram for describing a manufacturing method of the semiconductor module 1 illustrated in FIG. 1. First, as illustrated by reference sign S1 in FIG. 2, a semiconductor layer 13G, which is a base of the light-emitting element 13, is provided on a growth substrate GB. The growth substrate GB is a substrate for epitaxially growing the semiconductor layer 13G. After the semiconductor layer 13G is provided on the growth substrate GB, the semiconductor layer 13G is divided into the plurality of light-emitting elements 13 by forming a plurality of separation grooves 13A in the semiconductor layer 13G as illustrated by reference sign S2 in FIG. 2. Note that in FIG. 2, the separation groove 13A is formed to have a depth from a surface of the semiconductor layer 13G to the growth substrate GB, but the separation groove 13A may not be formed to have the depth reaching the growth substrate GB, and the light-emitting elements 13 may have a portion that is not separated from each other.

After the plurality of separation grooves 13A and electrodes (not illustrated) are formed in the semiconductor layer 13G, the underlayer substrate 11 on which the drive circuit and the plurality of electrodes 12 are formed is prepared as illustrated by reference sign S3 in FIG. 2. The underlayer substrate 11 and the growth substrate GB are made to face each other, and the plurality of electrodes 12 and the plurality of light-emitting elements 13 are bonded. After the plurality of electrodes 12 and the plurality of light-emitting elements 13 are bonded, the growth substrate GB is peeled off from the plurality of light-emitting elements 13.

After the growth substrate GB is peeled off from the plurality of light-emitting elements 13, the separation layer 16 is filled onto the underlayer substrate 11 so as to cover the upper face of the underlayer substrate 11, the electrodes 12, and the light-emitting elements 13 as illustrated by reference sign S4 in FIG. 2. After the separation layer 16 is filled onto the underlayer substrate 11, the color conversion layer 14 is formed on the plurality of light-emitting elements 13 and the separation layer 16 as illustrated by reference sign S5 in FIG. 2. Examples of a film formation method of the color conversion layer 14 include coating, vapor deposition, sputtering, and chemical vapor deposition (CVD).

After the color conversion layer 14 is formed on the plurality of light-emitting elements 13 and the separation layer 16, the protection layer 15 is formed on the color conversion layer 14 as illustrated by reference sign S6 in FIG. 2. A film formation method of the protection layer 15 may be similar to the film formation method of the color conversion layer 14. Note that manufacturing methods of the semiconductor modules 1A, 2, 2A, and 2B described later are similar to the manufacturing method of the semiconductor module 1 described here.

### Configuration of Semiconductor Module 1A

As illustrated by reference numeral 102 in FIG. 1, the semiconductor module 1A differs from the semiconductor module 1 in that the color conversion layer 14 and the protection layer 15 are changed to a color conversion layer 14A and a protection layer 15A, respectively. A material of a portion other than the color conversion material and the light scattering material in the color conversion layer 14A is a resin, which is the same as a material of the protection layer 15A.

Further, the color conversion layer 14A and the protection layer 15A are integrated. In this case, a portion of the color conversion layer 14A contains the color conversion material and the light scattering material, and a portion of the protection layer 15A does not contain the color conversion material or the light scattering material. Since the color conversion layer 14A and the protection layer 15A are integrated, the number of times the color conversion layer 14A and the protection layer 15A are formed can be reduced to one, and the manufacturing process can be reduced.

### Configuration of Semiconductor Module 1B

As illustrated by reference numeral 103 in FIG. 1, the semiconductor module 1B differs from the semiconductor module 1 in that a function layer 17 is formed. The semiconductor module 1B includes the function layer 17 formed on the protection layer 15. That is, the function layer 17 is formed on the upper side of the color conversion layer 14 with the protection layer 15 interposed therebetween.

The function layer 17 is configured to transmit the light emitted from the light-emitting element 13 and color-converted by the color conversion layer 14. When the function layer 17 has a high transmittance of light, the color-converted light can be efficiently emitted to the outside, and the semiconductor module 1B can be used as a display element with higher efficiency. Thus, the function layer 17 is preferably configured such that the transmittance of the light color-converted by the color conversion layer 14 is 50% or greater.

The function layer 17 reflects or absorbs the light emitted from the light-emitting element 13. As the function layer 17, for example, a color filter or a reflective film is used. When the function layer 17 is the color filter, the function layer 17 is constituted of a resin containing a pigment that absorbs light having no specific wavelength. Additionally, the function layer 17 may be constituted of a plurality of materials, for example, may be constituted of both the color filter and the reflective film. Here, the function layer 17 absorbs blue light emitted from the light-emitting element 13 and transmitted through the color conversion layer 14. By using the color filter as the function layer 17, the color of the light emitted from the semiconductor module 1B can be changed to a desired color.

When the function layer 17 is the reflective film, the function layer 17 has wavelength selectivity for transmitting light having a specific wavelength. Examples of the reflective film include a dielectric multilayer film in which the wavelength range of the reflected light changes depending on the angle of incident light, and examples of the dielectric multilayer film include a multilayer dielectric film in which different oxide layers are alternately layered. Here, the function layer 17 reflects 50% or greater of the blue light emitted from the light-emitting element 13 and transmitted through the color conversion layer 14.

In addition, as described above, the unevenness generated on the upper face of the color conversion layer 14 can be reduced by the protection layer 15, and the generation of micro-cracks in the function layer 17 due to this unevenness can be reduced because the function layer 17 is formed on the upper face of the protection layer 15 with improved flatness. As a result, the function layer 17 can be fully functional. In addition, since the unevenness of the upper face of the color conversion layer 14 is reduced, the function layer 17 having a uniform thickness can be formed on the entire surface of the color conversion layer 14, so that it is easy to make the light emission characteristics of the respective pixels uniform.

### Manufacturing Method of Semiconductor Module 1B

A manufacturing method of the semiconductor module 1B is similar to the manufacturing method of the semiconductor module 1 up to the step of forming the protection layer 15 on the color conversion layer 14. After the protection layer 15 is formed on the color conversion layer 14, the function layer 17 is formed on the protection layer 15. A film formation method of the function layer 17 may be similar to the film formation method of the color conversion layer 14.

Since the protection layer 15 is formed on the color conversion layer 14, when the function layer 17 is formed on the protection layer 15, the influence of the film formation of the function layer 17 on the color conversion layer 14 can be reduced. As a result, the light extraction efficiency from the color conversion layer 14 can be improved. In addition, since the protection layer 15 and the function layer 17 are formed on the upper side of the color conversion layer 14, the color conversion layer 14 is shielded from the atmosphere, so that deterioration over time of the color conversion layer 14 can be suppressed. Thus, it is also possible to suppress deterioration of the color conversion material contained in the color conversion layer 14.

### Second Embodiment

A second embodiment of the present disclosure will be described below. Note that, for convenience of explanation, components having functions identical to those in the first embodiment will be denoted by the same reference numerals, and descriptions of those components will be omitted. Similarly, in the third embodiment and subsequent embodiments, descriptions of the components described in the previous embodiments will not be repeated.

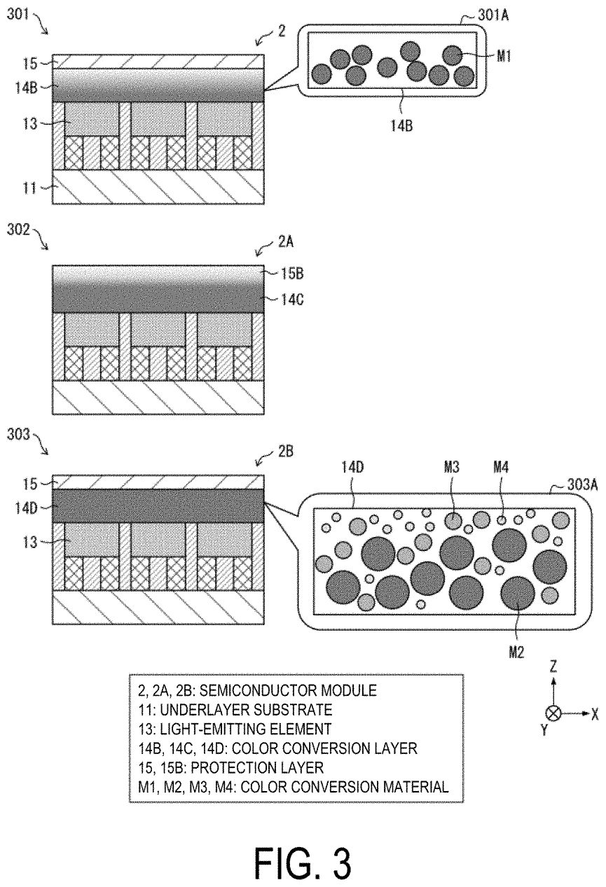

FIG. 3 is cross-sectional views illustrating configurations of semiconductor modules 2, 2A, and 2B according to the second embodiment of the present disclosure. The semiconductor modules 2A and 2B are modified examples of the semiconductor module 2. Reference numerals 301, 302, and 303 in FIG. 3 indicate the configurations of the semiconductor modules 2, 2A, and 2B, respectively. Note that features of color conversion layers 14B, 14C, and 14D described in the second embodiment may also be applied to color conversion layers described in other embodiments.

### Configuration of Semiconductor Module 2

As illustrated by reference numeral 301 in FIG. 3, the semiconductor module 2 differs from the semiconductor module 1 in that the color conversion layer 14 is changed to the color conversion layer 14B. Reference sign 301A schematically denotes the color conversion layer 14B and a color conversion material M1 contained in the color conversion layer 14B, and the size of the color conversion material M1 indicated by reference sign 301A is different from the size of the actual color conversion material M1.

As illustrated by reference sign 301A, the distribution of the color conversion material M1 inside the color conversion layer 14B is not uniform. The color conversion material M1 contained in the color conversion layer 14B may be present more on the light-emitting element 13 side of the color conversion layer 14B than on the side opposite to the light-emitting element 13 side of the color conversion layer 14B. For example, when the color conversion layer 14B is divided into two at the center in the thickness direction (Z direction in FIG. 3), the amount of the color conversion material M1 present in the lower half is greater than the amount of the color conversion material M1 present in the upper half.

In other words, the color conversion material M1 is present more on the light-emitting element 13 side of the color conversion layer 14B than on the protection layer 15 side of the color conversion layer 14B. The amount of the color conversion material M1 present may be expressed, for example, in terms of volume % or mass % of the color conversion material M1 in the color conversion layer 14B, or the number of particles of the color conversion material M1 in the color conversion layer 14B.

As a result, the amount of the color conversion material M1 present on the protection layer 15 side of the color conversion layer 14B is small, and thus the number of particles of the color conversion material M1 present in the vicinity of the upper face of the color conversion layer 14B is also small. Thus, it is possible to reduce the occurrence of unevenness on the upper face of the color conversion layer 14B due to the particles of the color conversion material M1. Thus, the flatness of the upper face of the color conversion layer 14B can be improved as compared with a case in which the color conversion material M1 is uniformly present inside the color conversion layer.

### Configuration of Semiconductor Module 2A

As illustrated by reference numeral 302 in FIG. 3, the semiconductor module 2A differs from the semiconductor module 2 in that the color conversion layer 14B and the protection layer 15 are changed to a color conversion layer 14C and a protection layer 15B, respectively. The color conversion layer 14C and the protection layer 15B are the same as the color conversion layer 14B and the protection layer 15 except for contents described here. A material of a portion other than the color conversion material M1 and the light scattering material in the color conversion layer 14C is a resin, which is the same as a material of the protection layer 15B.

Further, the color conversion layer 14C and the protection layer 15B are integrated. In this case, a portion of the color conversion layer 14C contains the color conversion material M1 and the light scattering material, and a portion of the protection layer 15B does not contain the color conversion material M1 or the light scattering material. Since the color conversion layer 14C and the protection layer 15B are integrated, the number of times the color conversion layer 14C and the protection layer 15B are formed can be reduced to one, and the manufacturing process can be reduced.

### Configuration of Semiconductor Module 2B

As illustrated by reference numeral 303 in FIG. 3, the semiconductor module 2B differs from the semiconductor module 2 in that the color conversion layer 14B is changed to the color conversion layer 14D. Reference sign 303A schematically denotes the color conversion layer 14D and color conversion materials M2, M3, and M4 contained in the color conversion layer 14D.

The sizes of the color conversion materials M2, M3, and M4 illustrated by reference sign 303A are different from the sizes of the actual color conversion material M2, M3, and M4. Further, the color conversion layer 14D includes three sizes of color conversion materials M2, M3, and M4. However, not limited thereto, two or four or more sizes of color conversion materials may be contained.

The color conversion layer 14D contains, for example, color conversion materials M2, M3, and M4 as color conversion materials of various sizes. The particles of the color conversion material M2 are larger than the particles of the color conversion material M3, and the particles of the color conversion material M3 are larger than the particles of the color conversion material M4.

The particles of the color conversion material M2 are present more on the light-emitting element 13 side of the color conversion layer 14D than on the protection layer 15 side of the color conversion layer 14D. The particles of the color conversion material M3 are uniformly present inside the color conversion layer 14D. The particles of the color conversion material M4 are present more on the protection layer 15 side of the color conversion layer 14D than on the light-emitting element 13 side of the color conversion layer 14D.

That is, many particles of the large color conversion material M2 are present on the light-emitting element 13 side, and many particles of the small color conversion material M4 are present on the protection layer 15 side. As a result, in the vicinity of the upper face of the color conversion layer 14D, many particles of the small color conversion material M4 and few particles of the large color conversion material M2 are present. Thus, the unevenness generated on the surface of the color conversion layer 14D on the protection layer 15 side is reduced, and the flatness of the upper face of the color conversion layer 14D can be improved.

Further, the volume occupied by the color conversion material in the color conversion layer 14D is larger on the light-emitting element 13 side of the color conversion layer 14D than on the protection layer 15 side of the color conversion layer 14D. Thus, overall, the color conversion material contained in the color conversion layer 14D is present more on the light-emitting element 13 side of the color conversion layer 14D than on the side opposite to the light-emitting element 13 side of the color conversion layer 14D.

### Third Embodiment

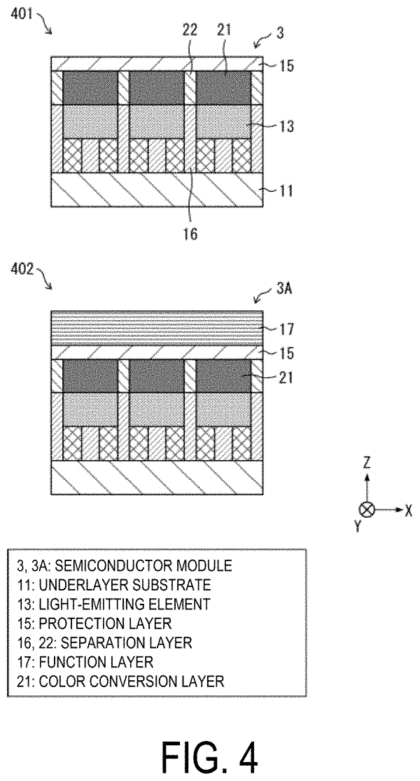

FIG. 4 is cross-sectional views illustrating configurations of semiconductor modules 3 and 3A according to a third embodiment of the present disclosure. The semiconductor module 3A is a modified example of the semiconductor module 3. Reference numerals 401 and 402 in FIG. 4 indicate configurations of the semiconductor modules 3 and 3A, respectively.

### Configuration of Semiconductor Module 3

As illustrated by reference numeral 401 in FIG. 4, the semiconductor module 3 differs from the semiconductor module 1 in that the semiconductor module 3 has a plurality of color conversion layers 21 and that a separation layer 22 is formed. The semiconductor module 3 includes the separation layer 22. The plurality of color conversion layers 21 are formed on upper faces of the plurality of light-emitting elements 13, respectively. The separation layer 22 is arranged between the color conversion layers 21 adjacent to each other, and is formed on the separation layer 16.

In other words, when the separation layers 16 and 22 are considered as one separation layer, the separation layer is arranged between the light-emitting elements 13 adjacent to each other and between the color conversion layers 21 adjacent to each other. This can reduce the influence of light between the light-emitting elements 13 and the influence of light between the color conversion layers 21, so that the light emitted from each light-emitting element 13 can be emphasized.

Further, it is preferable that the separation layer 22 be a light shielding layer having a visible light transmittance of not greater than 50%. This can reduce the amount of visible light passing between the color conversion layers 21 adjacent to each other. Furthermore, a visible light transmittance of the separation layer 16 is preferably not greater than 50%, which can reduce the amount of visible light passing between the light-emitting elements 13 adjacent to each other. Note that when a side surface of the separation layer 22 on the color conversion layer 21 side has a tapered shape such that a width of the separation layer 22 decreases toward the upward direction, the light extraction efficiency from the color conversion layer 21 can be improved. The width of the separation layer 22 is a width along the direction in which the color conversion layers 21 are aligned.

Note that, in the semiconductor module 3, the light-emitting elements 13 may be partially separated from each other such that the light-emitting elements 13 are separated from each other by the separation layer 16 on the underlayer substrate 11 side, while the light-emitting elements 13 are connected to each other on the side opposite to the underlayer substrate 11 side.

When there is a plurality of the color conversion layers 21 and the separation layer 22 is formed, the protection layer 15 is formed on the plurality of color conversion layers 21 and the separation layer 22. In the semiconductor module 3, the plurality of color conversion layers 21 are the same type of color conversion layers that convert the light emitted by the light-emitting elements 13 into light of the same color.

### Manufacturing Method of Semiconductor Module 3

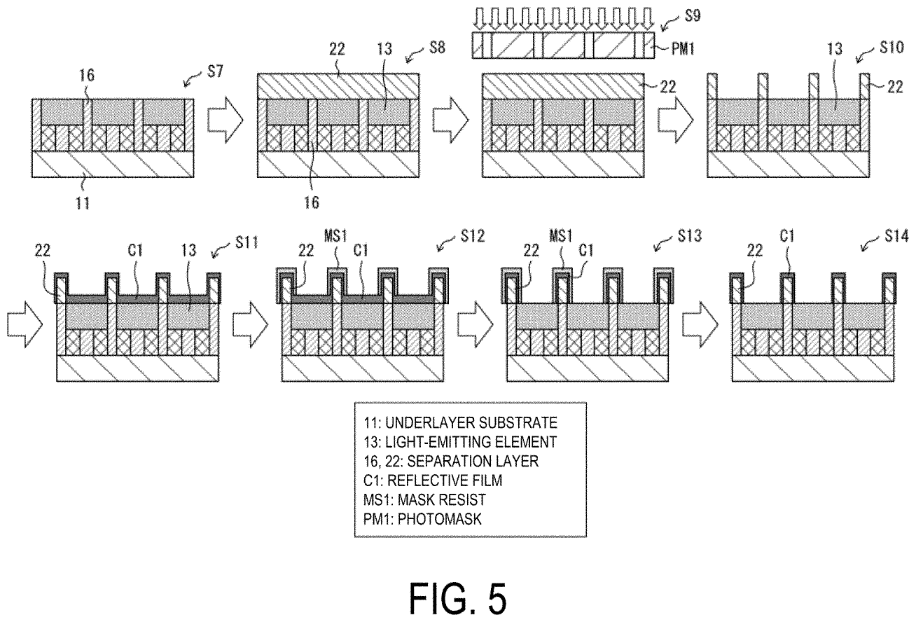

FIG. 5 is a diagram for describing a manufacturing method of the semiconductor module 3 illustrated in FIG. 4. The manufacturing method of the semiconductor module 3 is similar to the manufacturing method of the semiconductor module 1 up to the step of forming the separation layer 16. In a state illustrated by reference sign S7 in FIG. 5, after the separation layer 16 is filled onto the underlayer substrate 11, the separation layer 22 is formed on the plurality of light-emitting elements 13 and the separation layer 16 as illustrated by reference sign S8 in FIG. 5. Examples of the film formation method of the separation layer 22 include coating. A negative photoresist is used as the separation layer 22.

After the separation layer 22 is formed on the plurality of light-emitting elements 13 and the separation layer 16, the separation layer 22 is exposed by irradiating the separation layer 22 with light from above a photomask PM1 as illustrated by reference sign S9 in FIG. 5. As a result, as illustrated by reference sign S10 in FIG. 5, the separation layer 22 is developed to expose the upper faces of the plurality of light-emitting elements 13. Since the separation layer 22 is the negative photoresist, the exposed portion remains.

Subsequently, as illustrated by reference sign S11 in FIG. 5, a reflective film C1 is formed on the upper faces of the plurality of light-emitting elements 13 and the exposed face of the separation layer 22. Examples of a film formation method of the reflective film C1 include vapor deposition and sputtering, and examples of a material of the reflective film C1 include Al and Ag. After the reflective film C1 is formed on the upper faces of the plurality of light-emitting elements 13 and the exposed face of the separation layer 22, a mask resist MS1 is formed so as to cover the separation layer 22 with the reflective film C1 interposed therebetween as illustrated by reference sign S12 in FIG. 5.

After the mask resist MS1 is formed, the reflective film C1 is removed by etching as illustrated by reference sign S13 in FIG. 5. At this time, since the reflective film C1 formed on the exposed face of the separation layer 22 is covered with the mask resist MS1, the reflective film C1 remains without being removed by etching. After part of the reflective film C1 is removed by etching, the mask resist MS1 formed on the reflective film C1 is peeled off as illustrated by reference sign S14 in FIG. 5. Examples of etching include dry etching with a reactive gas such as C12, dry etching with sputtering using such as Ar, and wet etching with a chemical solution.

After the mask resist MS1 formed on the reflective film C1 is peeled off, a color conversion layer is applied on the plurality of light-emitting elements 13. As a result, the color conversion layers 21 are formed on the plurality of light-emitting elements 13, respectively, and the plurality of color conversion layers 21 are formed between portions of the separation layer 22. At this time, the reflective film C1 is formed between the color conversion layer 21 and the separation layer 22. After the color conversion layers 21 are formed on the plurality of light-emitting elements 13, respectively, the protection layer 15 is formed on the plurality of color conversion layers 21 and the separation layer 22.

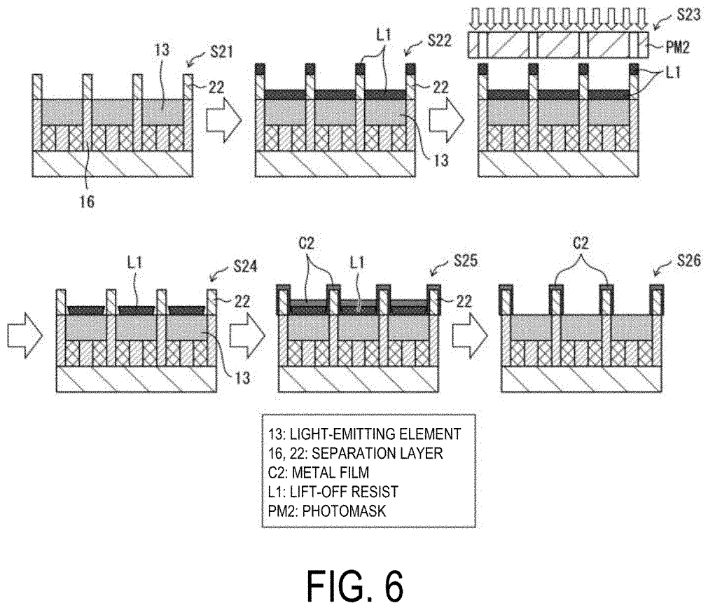

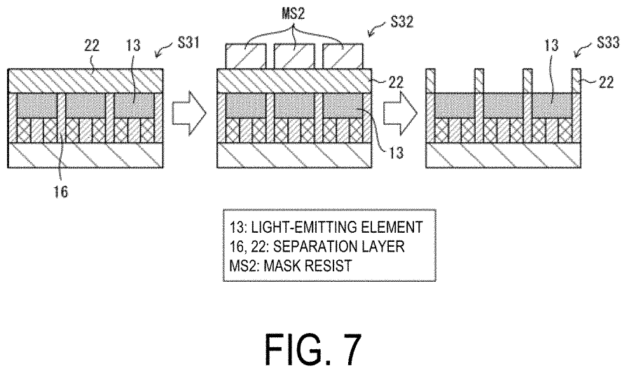

Note that, after the reflective film C1 is formed, anisotropic etching may be performed in which the etching rates of the reflective film C1 are different in the XY direction and the Z direction without the mask resist MS1. In addition, when the separation layer 22 is made of a material having light shielding properties, the steps of film formation and etching of the reflective film C1 are unnecessary. These are similar in other manufacturing methods, such as modified examples of the manufacturing method of the semiconductor module 3 described later with reference to FIGS. 6 and 7.

### First Modified Example of Manufacturing Method of Semiconductor Module 3

FIG. 6 is a diagram for describing a first modified example of the manufacturing method of the semiconductor module 3 illustrated in FIG. 4. The first modified example of the manufacturing method of the semiconductor module 3 is similar to the manufacturing method of the semiconductor module 3 up to the step in which the separation layer 22 is developed. After the separation layer 22 is formed on the plurality of light-emitting elements 13 and the separation layer 16 in a state illustrated by reference sign S21 in FIG. 6, a lift-off resist L1 is applied to the upper faces of the plurality of light-emitting elements 13 and the upper face of the separation layer 22 as illustrated by reference sign S22 in FIG. 6. In the first modified example, a positive photoresist is used as the lift-off resist L1.

After the lift-off resist L1 is applied to the upper faces of the plurality of light-emitting elements 13 and the upper face of the separation layer 22, the lift-off resist L1 is exposed to light by irradiating the lift-off resist L1 with light from above a photomask PM2 as illustrated by reference sign S23 in FIG. 6. As a result, as illustrated by reference numeral S24 in FIG. 6, the lift-off resist L1 is developed, and the lift-off resist L1 formed on the upper face of the separation layer 22 and the lift-off resist L1 formed in the vicinity of the boundary between the light-emitting element 13 and the separation layer 22 are removed. Since the lift-off resist L1 is the positive photoresist, unexposed portions remain.

Subsequently, as illustrated by reference sign S25 in FIG. 6, a metal film C2 is formed on an upper face of the lift-off resist L1 remaining on the upper faces of the plurality of light-emitting elements 13 and the exposed face of the separation layer 22. After the metal film C2 is formed, the lift-off resist L1 and the metal film C2 remaining on the upper faces of the plurality of light-emitting elements 13 are peeled off as illustrated by reference sign S26 in FIG. 6. The subsequent step of forming the color conversion layer 21 is similar to that of the manufacturing method of the semiconductor module 3.

### Second Modified Example of Manufacturing Method of Semiconductor Module 3

FIG. 7 is a diagram for describing a second modifies example of the manufacturing method of the semiconductor module 3 illustrated in FIG. 4. The second modified example of the manufacturing method of the semiconductor module 3 is similar to the manufacturing method of the semiconductor module 3 up to the step of forming the separation layer 22. In the second modified example, a material that cannot be processed by photolithography, for example, a resin material, an inorganic material such as SiO₂, or a resin material containing inorganic material particles is used as the separation layer 22.

In a state illustrated by reference sign S31 in FIG. 7, after the separation layer 22 is formed on the plurality of light-emitting elements 13 and the separation layer 16, a mask resist is formed on the separation layer 22. After the mask resist is applied on the separation layer 22, the mask resist is exposed by irradiating the mask resist with light from above a photomask (not illustrated). As a result, as illustrated by reference sign S32 in FIG. 7, the mask resist is developed, and a plurality of mask resists MS2 are arranged on the upper side of the light-emitting elements 13, respectively, with the separation layer 22 interposed therebetween.

Subsequently, as illustrated by reference sign S33 in FIG. 7, part of the separation layer 22 is removed by etching, and the mask resists MS2 are then peeled off. After the mask resists MS2 are peeled off, the reflective film C1 is formed on the exposed face of the separation layer 22, and the color conversion layers 21 are formed on the plurality of light-emitting elements 13, respectively, similar to the manufacturing method of the semiconductor module 3.

### Configuration of Semiconductor Module 3A

As illustrated by reference numeral 402 in FIG. 4, the semiconductor module 3A differs from the semiconductor module 3 in that the function layer 17 is formed. The function layer 17 is formed on the upper side of the plurality of color conversion layers 21 with the protection layer 15 interposed therebetween. Thus, one aspect of the present disclosure is not limited to a configuration in which the function layer 17 is formed on the upper side of the single color conversion layer 14 as in the semiconductor module 1B, but also includes a configuration in which the function layer 17 is formed on the upper side of the plurality of color conversion layers 21.

### Fourth Embodiment

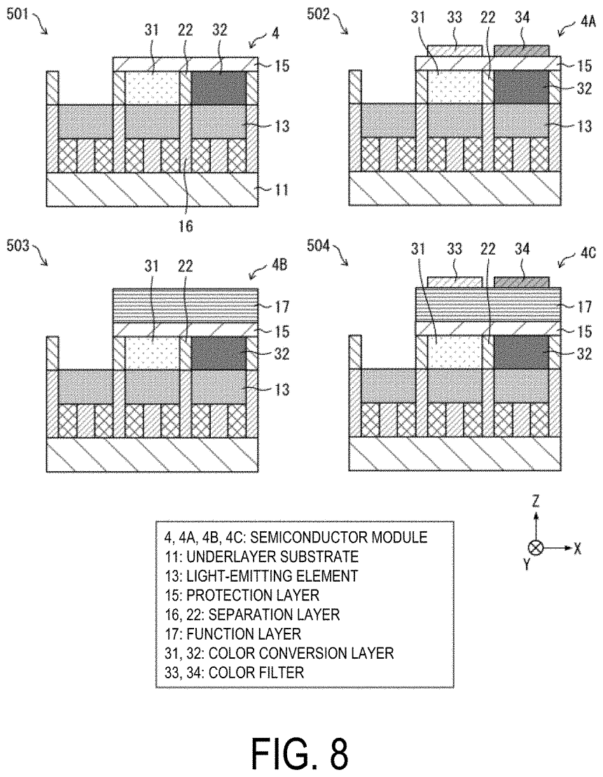

FIG. 8 is cross-sectional views illustrating configurations of semiconductor modules 4, 4A, 4B, and 4C according to a fourth embodiment of the present disclosure. The semiconductor modules 4A, 4B, and 4C are modified examples of the semiconductor module 4. Reference numerals 501, 502, 503, and 504 in FIG. 8 indicate the configurations of the semiconductor modules 4, 4A, 4B, and 4C, respectively.

### Configuration of Semiconductor Module 4

As illustrated by reference numeral 501 in FIG. 8, the semiconductor module 4 differs from the semiconductor module 3 in that the plurality of color conversion layers 21 are changed to color conversion layers 31 and 32. Further, the semiconductor module 4 differs from the semiconductor module 3 in that the color conversion layers 31 and 32 and the protection layer 15 are formed only on the upper side of some light-emitting elements 13 among the plurality of light-emitting elements 13.

The color conversion layers 31 and 32 are formed on some light-emitting elements 13 among the plurality of light-emitting elements 13, respectively. The color conversion layer 31 is a green conversion layer that converts the light emitted by the light-emitting element 13 into green light. The color conversion layer 32 is a red conversion layer that converts the light emitted by the light-emitting element 13 into red light. The protection layer 15 is formed on the color conversion layers 31 and 32 and is also formed on the separation layer 22 surrounding the color conversion layers 31 and 32. Note that, in the semiconductor module 4, the light-emitting elements 13 may be partially separated from each other such that the light-emitting elements 13 are separated from each other by the separation layer 16 on the underlayer substrate 11 side, while the light-emitting elements 13 are connected to each other on the side opposite to the underlayer substrate 11 side.

On the other hand, among the plurality of light-emitting elements 13, the color conversion layers 31 and 32 and the protection layer 15 are not formed on the upper side of the other light-emitting elements 13. In other words, the color conversion layers 31 and 32 and the protection layer 15 are formed on the upper side of at least some light-emitting elements 13 among the plurality of light-emitting elements 13. As a result, the color conversion layers 31 and 32 can be used to emit light in various luminescent colors. Thus, by controlling the light emission state of the respective light-emitting elements 13, the semiconductor module 4 can be used as a display element such as a display.

### Manufacturing Method of Semiconductor Module 4

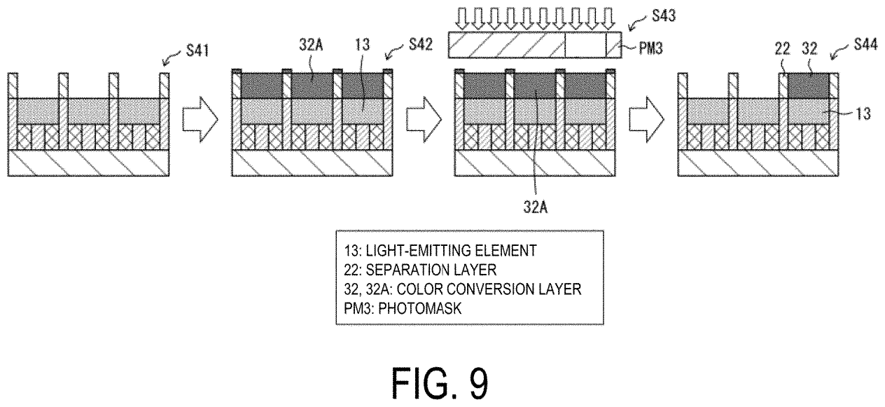

FIG. 9 is a diagram for describing a manufacturing method of the semiconductor module 4 illustrated in FIG. 8. In this example, negative photoresists containing color conversion materials, respectively, are used to form the color conversion layers 31 and 32, respectively. The manufacturing method of the semiconductor module 4 is similar to the manufacturing method of the semiconductor module 3 up to the step of forming the color conversion layers 21 on the plurality of light-emitting elements 13, respectively. As illustrated by reference signs S41 and S42 in FIG. 9, a color conversion layer 32A is applied on each of the plurality of light-emitting elements 13.

After the color conversion layer 32A is applied to each of the plurality of light-emitting elements 13, the color conversion layer 32A is exposed by irradiating the color conversion layer 32A with light from above a photomask PM3 as illustrated by reference sign S43 in FIG. 9. As a result, as illustrated by reference sign S44 in FIG. 9, the color conversion layer 32A is developed, and some upper faces of the light-emitting elements 13 are exposed.

Thus, the color conversion layer 32 is formed on the other light-emitting element 13. The color conversion layer 31 is formed on the light-emitting element 13 in a similar manner as the color conversion layer 32. After the color conversion layers 31 and 32 are formed on some light-emitting elements 13, the protection layer 15 is formed on the color conversion layers 31 and 32 and on the separation layer 22 surrounding the color conversion layers 31 and 32.

Note that the color conversion layer 31 can also be formed by the method illustrated in FIG. 7. After the color conversion layer 31 is formed on all the light-emitting elements 13 and the separation layer 16, a mask resist is formed, and the color conversion layer 31 is formed only on the specific light-emitting element 13 by etching. The color conversion layer 32 can also be formed in a similar manner.

Note that, in the semiconductor module 4B described later, after the protection layer 15 is formed, the function layer 17 is formed on the protection layer 15 by coating, vapor deposition, sputtering, or the like. Further, in the semiconductor module 4C described later, after the function layer 17 is formed on the protection layer 15, the color filters 33 and 34 are formed on the function layer 17 by coating, vapor deposition, sputtering, or the like.

Examples of the method of patterning the color conversion layer, the protection layer, the function layer, and the color filter in the fourth embodiment include (1) using a photoresist as a material and patterning in a photolithography step, and (2) forming a mask resist after film formation, and patterning by etching, or the like. This also applies to the other embodiments.

### Configuration of Semiconductor Module 4A

As illustrated by reference numeral 502 in FIG. 8, the semiconductor module 4A differs from the semiconductor module 4 in that the color filters 33 and 34 are formed. The semiconductor module 4A includes the color filters 33 and 34.

The color filter 33 is formed on the upper side of the color conversion layer 31 with the protection layer 15 interposed therebetween. The color filter 33 is formed on the protection layer 15 and transmits only green light from various colors of light emitted from the light-emitting element 13 and passing through the color conversion layer 31. The color filter 34 is formed on the upper side of the color conversion layer 32 with the protection layer 15 interposed therebetween. The color filter 34 is formed on the protection layer 15 and transmits only red light from various colors of light emitted from the light-emitting element 13 and passing through the color conversion layer 32. By forming these color filters, it is possible to increase the color purity and further suppress undesired light emission due to external light.

In addition, since the protection layer 15 is formed between the color conversion layers 31 and 32 and the color filters 33 and 34, it is possible to reduce the influence of the unevenness generated on the upper face of the color conversion layers 31 and 32 on the color filters 33 and 34. Thus, the functions of the color filters 33 and 34 can be fully exhibited.

### Configuration of Semiconductor Module 4B

As illustrated by reference numeral 503 in FIG. 8, the semiconductor module 4B differs from the semiconductor module 4 in that the function layer 17 is formed. The function layer 17 is formed on the protection layer 15 formed only on the upper side of some light-emitting elements 13 among the plurality of light-emitting elements 13. In other words, the function layer 17 is formed only on the upper side of some light-emitting elements 13 among the plurality of light-emitting elements 13. Thus, one aspect of the present disclosure is not limited to the configuration in which the function layer 17 is formed on the upper side of all the light-emitting elements 13 as in the semiconductor module 1B, but also includes a configuration in which the function layer 17 is formed on the upper side of some light-emitting elements 13. Since the function layer 17 is formed, the usage efficiency of light of the light-emitting element 13 can be improved.

### Configuration of Semiconductor Module 4C

As illustrated by reference numeral 504 in FIG. 8, the semiconductor module 4C differs from the semiconductor module 4B in that the color filters 33 and 34 are formed. The color filters 33 and 34 are formed on the function layer 17. The color filter 33 is formed on the upper side of the color conversion layer 31 with the protection layer 15 and the function layer 17 interposed therebetween. The color filter 34 is formed on the upper side of the color conversion layer 32 with the protection layer 15 and the function layer 17 interposed therebetween. By forming these color filters, it is possible to increase the color purity and further suppress undesired light emission due to external light.

In addition, a separation layer that shields visible light can be formed in the function layer 17 of the semiconductor modules 4B and 4C. The separation layer is formed on the separation layer 22 in a top view. This can reduce the influence of light between the light-emitting elements 13, the influence of light between the color conversion layers 31 and 32, and the influence of the light between the function layers 17. Therefore, the light emitted from each of the light-emitting elements 13 can be emphasized.

### Fifth Embodiment

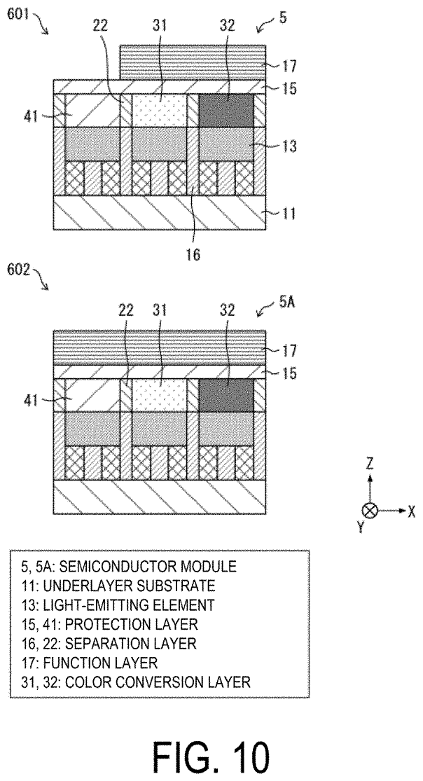

FIG. 10 is cross-sectional views illustrating configurations of semiconductor modules 5 and 5A according to a fifth embodiment of the present disclosure. The semiconductor module 5A is a modified example of the semiconductor module 5. Reference numerals 601 and 602 in FIG. 10 indicate the configurations of the semiconductor modules 5 and 5A, respectively.

### Configuration of Semiconductor Module 5

As illustrated by reference numeral 601 in FIG. 10, the semiconductor module 5 differs from the semiconductor module 4B in that a protection layer 41 is formed on some light-emitting elements 13 among the plurality of light-emitting elements 13. A material of the protection layer 41 is the same as that of the protection layer 15, and the protection layer 41 is integrated with the protection layer 15. However, the material of the protection layer 41 is not limited thereto, and the material of the protection layer 41 may be different from the material of the protection layer 15.

In addition, when the protection layer 41 is made of a material different from the material of the protection layer 15, the protection layer 41 may contain a light scattering material. The presence of the light scattering material makes it easy to bring the light emitting characteristics on the light-emitting elements 13 on which the color conversion layers 31 and 32 are formed, respectively and the light emitting characteristics on the light-emitting element 13 on which the protection layer 41 is formed close to each other. Note that the semiconductor module 5 according to the fifth embodiment can be used as a display element such as a display by controlling the light emission state of the respective light-emitting elements 13 as in the semiconductor module 4 according to the fourth embodiment. Note that, in the semiconductor module 5, the light-emitting elements 13 may be partially separated from each other such that the light-emitting elements 13 are separated from each other by the separation layer 16 on the underlayer substrate 11 side, while the light-emitting elements 13 are connected to each other on the side opposite to the underlayer substrate 11 side.

In the light-emitting element 13 on which the color conversion layers 31 and 32 are not formed, the protection layer 41 and the protection layer 15 are formed on this light-emitting element 13, the light-emitting element 13 is shielded from the atmosphere, so that deterioration over time of the light-emitting element 13 can be suppressed.

In addition, when the protection layer 15 is formed, a surface having a substantially uniform height is formed by the separation layer 22, the protection layer 41, and the color conversion layers 31 and 32, as compared with a case in which the protection layer 41 is not formed. As a result, the protection layer 15 can be easily formed, and the unevenness of the surface of the protection layer 15 facing the light-emitting element 13 can be suppressed.

The protection layer 15 is not only formed on the color conversion layers 31 and 32, but also on the protection layer 41 and also on the separation layer 22 surrounding the protection layer 41. The function layer 17 is formed on the upper side of the color conversion layers 31 and 32 with the protection layer 15 interposed therebetween, but is not formed on the upper side of the protection layer 41. In other words, the function layer 17 is formed on the upper side of some light-emitting elements 13 among the plurality of light-emitting elements 13.

### Configuration of Semiconductor Module 5A

As illustrated by reference numeral 602 in FIG. 10, the semiconductor module 5A differs from the semiconductor module 5 in that the function layer 17 is formed on the upper side of all the light-emitting elements 13. That is, the function layer 17 is formed not only on the upper side of the color conversion layers 31 and 32, but also on the upper side of the protection layer 41 with the protection layer 15 interposed therebetween. Thus, one aspect of the present disclosure is not limited to a configuration in which the function layer 17 is formed only on the upper side of some light-emitting elements 13 as in the semiconductor module 5, but also includes a configuration in which the function layer 17 is formed on the upper side of all the light-emitting elements 13.

As another modified example, although not illustrated, a violet light-emitting element can be used as the light-emitting element 13, and a color conversion layer containing a blue light emitting material can be formed instead of the protection layer 41. This also allows the semiconductor module to be used as a display element such as a display. In addition, in this case, the function layer 17 has a function of wavelength-selectively reflecting violet. As a result, in particular, in the structure of the semiconductor module 5A, the light utilization of the light-emitting element 13 can be enhanced, and a more efficient semiconductor module can be obtained.

As yet another modified example, color filters may be formed on the function layers 17 of the semiconductor modules 5 and 5A, respectively. By forming these color filters, it is possible to increase the color purity and further suppress undesired light emission due to external light.

In addition, a separation layer that shields visible light can be formed in the function layers 17 of the semiconductor modules 5 and 5A, respectively. The separation layer is formed on the separation layer 22 in a top view. This can reduce the influence of light between the light-emitting elements 13, the influence of light between the color conversion layers 31 and 32, and the influence of the light between the function layers 17. Therefore, the light emitted from each of the light-emitting elements 13 can be emphasized.

### EXAMPLES

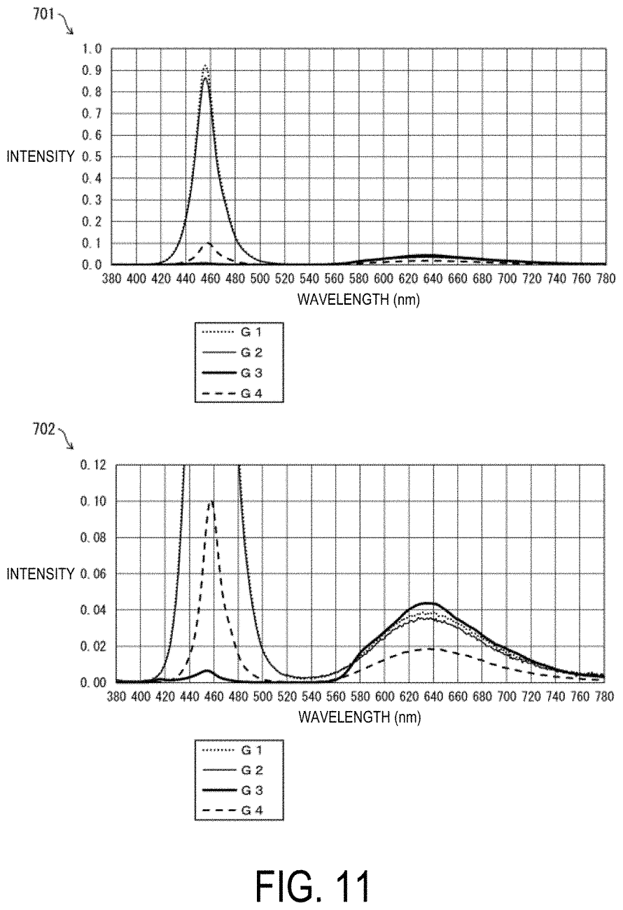

Hereinafter, one aspect of the present disclosure will be described in more detail using examples, but the one aspect of the present disclosure is not limited to these examples. FIG. 11 is a diagram showing the intensity of light emitted from the semiconductor module according to one example of the one aspect of the present disclosure. In reference numeral 701 in FIG. 11, the horizontal axis represents the wavelength [nm] of the light emitted from the semiconductor module, and the vertical axis represents the intensity of the light emitted from the semiconductor module. Reference numeral 702 in FIG. 11 is an enlarged diagram of a range in which the light intensity is from 0.00 to 0.12 in the figure shown by reference numeral 701 in FIG. 11.

Line G1 indicates a case in which the color conversion layer 14 is formed on the light-emitting element 13, but the protection layer 15 is not formed on the color conversion layer 14. Line G2 indicates a case in which the color conversion layer 14 is formed on the light-emitting element 13, and the protection layer 15 is formed on the color conversion layer 14. Line G3 indicates a case in which the color conversion layer 14 and protection layer 15 are formed on the upper side of light-emitting element 13, and the function layer 17 is formed on the protection layer 15. Line G4 indicates a case in which the color conversion layer 14 and the function layer 17 are formed on the upper side of the light-emitting element 13, but the protection layer 15 is not formed on the upper side of the color conversion layer 14.

As indicated by reference numeral 702 in FIG. 11, in Line G3, the intensity of light became smaller in the vicinity of 455 nm, which is the wavelength of blue light, than in the other cases. This is because that the flatness was improved by forming the protection layer 15 on the upper side of the color conversion layer 14, and the function of the function layer 17 formed on the protection layer 15 was fully exhibited, whereby blue light could be further reflected.

In addition, in Line G3, the intensity of light became stronger in the vicinity of the wavelength of 640 nm than in the case of Line G4. Similarly, this is because that the flatness was improved by forming the protection layer 15 on the upper side of the color conversion layer 14, and the function of the function layer 17 formed on the protection layer 15 was fully exhibited, whereby, blue light could be reflected. In addition, this is because the blue light reflected by the function layer 17 could increase the light emission intensity from the color conversion layer 14.

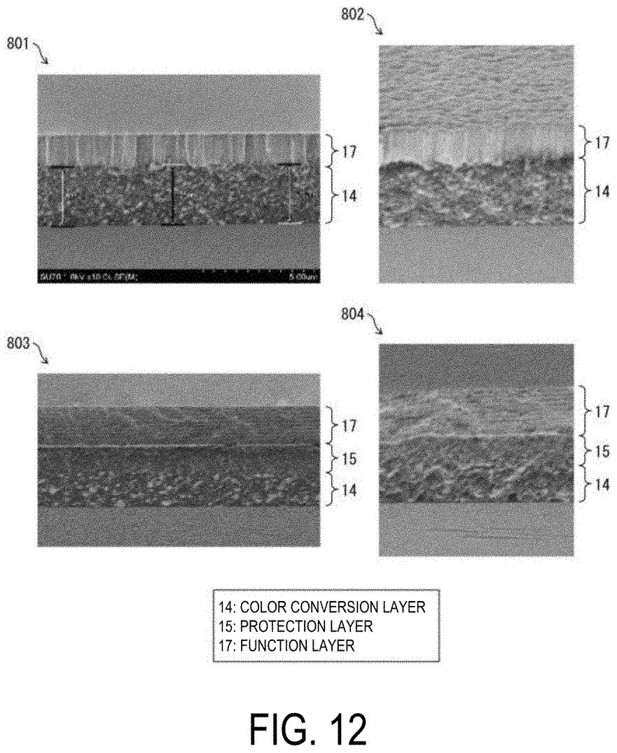

FIG. 12 is a diagram illustrating a cross sectional view of the color conversion layer 14 and the function layer 17 in the semiconductor module according to one example of one aspect of the present disclosure. In addition, FIG. 12 illustrates observation results with a scanning electron microscope (SEM). Further, reference numerals 801 and 803 in FIG. 12 indicate cross-sectional SEM images taken without tilting the semiconductor modules, and reference numerals 802 and 804 in FIG. 12 indicate cross-sectional SEM images taken by tilting the semiconductor modules toward the front side.

Reference numerals 801 and 802 in FIG. 12 indicate a case in which the function layer 17 is directly formed without forming the protection layer 15 on the color conversion layer 14. Reference numerals 803 and 804 in FIG. 12 indicate a case in which the protection layer 15 is formed on the color conversion layer 14, and the function layer 17 is formed on the protection layer 15.

As illustrated by reference numerals 801 and 802 in FIG. 12, when the protection layer 15 is not formed between the color conversion layer 14 and the function layer 17, unevenness is generated on the upper face of the color conversion layer 14, and the unevenness causes micro-cracks in the function layer 17. As a result, the characteristics of the function layer 17 are not fully exhibited. On the other hand, as illustrated by reference numerals 803 and 804 in FIG. 12, when the protection layer 15 is formed between the color conversion layer 14 and the function layer 17, it is possible to reduce the occurrence of unevenness on the upper face of the color conversion layer 14. Further, it is possible to reduce the occurrence of micro-cracks in the function layer 17, and it is possible to fully exhibit the characteristics of the function layer 17.

### Supplement

A semiconductor module according to a first aspect of the present disclosure includes an underlayer substrate on which a drive circuit is formed, a light-emitting element electrically coupled to the drive circuit, and a color conversion layer formed on the light-emitting element and containing a color conversion material that absorbs light emitted from the light-emitting element and converts a luminescent color of the light-emitting element to another luminescent color, in which the color conversion material contained in the color conversion layer is present more on a light-emitting element side of the color conversion layer than on a side opposite to the light-emitting element side of the color conversion layer.

In the first aspect, the semiconductor module according to a second aspect of the present disclosure may further include a function layer formed on an upper side of the color conversion layer and having a transmittance of 50% or greater of the light emitted from the light-emitting element and color-converted by the color conversion layer.

In the second aspect, the semiconductor module according to a third aspect of the present disclosure may have a configuration in which the function layer reflects or absorbs the light emitted from the light-emitting element.

In any of the first to third aspects, the semiconductor module according to a fourth aspect of the present disclosure may further include a separation layer arranged between the color conversion layer and another color conversion layer adjacent to each other.

In the fourth aspect, the semiconductor module according to a fifth aspect of the present disclosure may have a configuration in which a visible light transmittance of the separation layer is 50% or less.

In any of the first to fifth aspects, the semiconductor module according to a sixth aspect of the present disclosure may further include a protection layer formed on the color conversion layer and configured to protect an upper portion of the color conversion layer, in which the color conversion layer and the protection layer are formed on an upper side of the light-emitting element.

A semiconductor module according to a seventh aspect of the present disclosure includes an underlayer substrate on which a drive circuit is formed, a light-emitting element electrically coupled to the drive circuit, a color conversion layer formed on the light-emitting element and configured to absorb light emitted from the light-emitting element and convert a luminescent color of the light-emitting element to another luminescent color, and a protection layer formed on the color conversion layer and configured to protect an upper portion of the color conversion layer.

In the seventh aspect, the semiconductor module according to an eighth aspect of the present disclosure may have a configuration in which flatness of a surface of the protection layer on a side opposite to a color conversion layer side is higher than flatness of a surface of the protection layer on the color conversion layer side.

### Supplementary Information

An aspect of the disclosure is not limited to each of the above-described embodiments. It is possible to make various modifications within the scope of the claims. An embodiment obtained by appropriately combining technical elements each disclosed in different embodiments falls also within the technical scope of the aspect of the disclosure. Furthermore, technical elements disclosed in the respective embodiments may be combined to provide a new technical feature.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A semiconductor module comprising:
an underlayer substrate on which a drive circuit is formed;
a light-emitting element electrically coupled to the drive circuit; and
a color conversion layer formed on the light-emitting element and containing a color conversion material that absorbs light emitted from the light-emitting element and converts a luminescent color of the light-emitting element to another luminescent color,
wherein the color conversion material contained in the color conversion layer is present more on a light-emitting element side of the color conversion layer than on a side opposite to the light-emitting element side of the color conversion layer.

2. The semiconductor module according to claim 1, further comprising:
a function layer formed on an upper side of the color conversion layer and having a transmittance of 50% or greater of the light emitted from the light-emitting element and color-converted by the color conversion layer.

3. The semiconductor module according to claim 2,
wherein the function layer reflects or absorbs the light emitted from the light-emitting element.

4. The semiconductor module according to claim 1, further comprising:
a separation layer arranged between the color conversion layer and another color conversion layer adjacent to each other.

5. The semiconductor module according to claim 4,
wherein a visible light transmittance of the separation layer is 50% or less.

6. The semiconductor module according to claim 1, further comprising:
a protection layer formed on the color conversion layer and configured to protect an upper portion of the color conversion layer,
wherein the color conversion layer and the protection layer are formed on an upper side of the light-emitting element.

7. A semiconductor module comprising:
an underlayer substrate on which a drive circuit is formed;
a light-emitting element electrically coupled to the drive circuit;
a color conversion layer formed on the light-emitting element and configured to absorb light emitted from the light-emitting element and convert a luminescent color of the light-emitting element to another luminescent color; and
a protection layer formed on the color conversion layer and configured to protect an upper portion of the color conversion layer.

8. The semiconductor module according to claim 7,
wherein flatness of a surface of the protection layer on a side opposite to a color conversion layer side is higher than flatness of a surface of the protection layer on the color conversion layer side.
